(19) United States
(12) Patent Application Publication
(10) Pub. No.: US 2007/0256859 A1
(43) Pub. Date: Nov. 8, 2007

(54) CERAMIC MULTILAYER SUBSTRATE AND ITS MANUFACTURING METHOD

(75) Inventors: Hiromichi KAWAKAMI, Echizen-shi (JP); Iwao FUJITA, Hakusan-shi (JP); Makoto TOSE, Kanazawa-shi (JP); Yoshifumi SAITO, Otsu-shi (JP); Masahiro KIMURA, Ogaki-shi (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(73) Assignee: MURATA MANUFACTURING CO., LTD., Nagaokakyo-shi (JP)

(21) Appl. No.: 11/777,354

(22) Filed: Jul. 13, 2007

Related U.S. Application Data
(63) Continuation of application No. PCT/JP2006/304162, filed on Mar. 3, 2006.

(30) Foreign Application Priority Data
Mar. 4, 2005 (JP) 2005-060769

(51) Int. Cl. H05K 1/16

(52) U.S. Cl. 174/260

(57) ABSTRACT

A ceramic multilayer substrate having excellent migration resistance and high bonding strength between a resin sealing material and a ceramic multilayer substrate body, includes a laminated substrate body having lands, and external electrodes, and covered with a siloxane film formed by a PVD process. The thickness of the siloxane film is lower than about 100 nm. After that, external electrodes of a mounting component are electrically connected and firmly hold to the lands of the laminated substrate body via solder. Next, a resin sealing material for sealing the mounting component is formed on the laminated substrate body.

### BACKGROUND OF THE INVENTION

1. Field of the Invention

The present invention relates to a ceramic multilayer substrate, especially, to a ceramic multilayer substrate for mounting an electronic component such as an IC component on a surface thereof, and its manufacturing method.

2. Description of the Related Art

In general, in a ceramic multilayer substrate, Ag— or Cu— based lands for mounting a mounting component and further external electrodes for mounting the multilayer substrate itself are formed on the substrate surface. On the lands and the external electrodes, a solderable and wire-bondable plating film is formed. The plating film also has an effect of suppressing the migration of the lands and the external electrodes.

However, previously, when a ceramic multilayer substrate was used under a high electric field, since the plating film formed on the lands and the external electrodes did not sufficiently suppress the migration, the formation of a protective film made of glass or resin in addition to the plating film has been required. Consequently, there have been problems related to design constraints and the increase in the manufacturing cost, due to the formation of the protective film.

Moreover, as described in Japanese Unexamined Patent Application Publication No. 2003-249840, in order to protect the mounting component mounted on the ceramic multilayer substrate, in some cases, the mounting component is sealed with a resin sealing material. However, since the wettability between the resin sealing material and the ceramic multilayer substrate body is not good, there has also been a problem that the bonding strength between the resin sealing material and the ceramic multilayer substrate body is not sufficient.

In addition, as for the technologies for forming a siloxane film via sputtering, they are described in Japanese Unexamined Patent Application Publication No. 06-152109 and Japanese Unexamined Patent Application Publication No. 08-213742.

### SUMMARY OF THE INVENTION

In order to overcome the problems described above, preferred embodiments of the present invention provide a ceramic multilayer substrate that has excellent migration resistance and high bonding strength between the resin sealing material and the ceramic multilayer substrate body, and its manufacturing method.

A ceramic multilayer substrate according to a first preferred embodiment of the present invention includes a laminated substrate body constituted by stacking a plurality of ceramic layers and inner conductor layers, lands provided on the surface of the laminated substrate body for being electrically connected to the external electrodes of the mounting component, and a siloxane film arranged so as to cover the laminated substrate body and the land, and having a thickness lower than about 100 nm.

As for the ceramic multilayer substrate according to a preferred embodiment of the present invention, further, it is preferable for the siloxane film to be arranged so as to cover the mounting component mounted on the lands via solder and at least a portion of the solder.

A ceramic multilayer substrate according to a second preferred embodiment of the present invention includes a laminated substrate body constituted by stacking a plurality of ceramic layers and inner conductor layers, lands provided on the surface of the laminated substrate body for being electrically connected to the external electrodes of the mounting component, a mounting component mounted on the lands via solder, and a siloxane film arranged so as to cover the laminated substrate body, the mounting component, and at least a portion of the solder, and having a thickness lower than about 100 nm.

As for the ceramic multilayer substrates according to the first and second preferred embodiments of the present invention, further the substrates preferably include a resin sealing material arranged to seal the mounting component. Further, it is preferable for the resin sealing material to be covered with a siloxane film.

The ceramic multilayer substrate according to a third preferred embodiment of the present invention includes a laminated substrate body constituted by stacking a plurality of ceramic layers and inner conductor layers, lands provided on the surface of the laminated substrate body for being electrically connected to the external electrodes of the mounting component, the mounting component mounted on the lands via solder, a resin sealing material arranged to seal the mounting component, and a siloxane film arranged so as to cover the laminated substrate body and the resin sealing material, and having a thickness lower than about 100 nm.

In the ceramic multilayer substrates according to the first to third preferred embodiments of the present invention, it is preferable for the mounting component to include an IC component and to be electrically connected to the lands via wire bonding. The IC component may be contained in a cavity provided on one principal surface of the laminated substrate body. Moreover, a plating film may also be formed on the lands.

A manufacturing method of a ceramic multilayer substrate according to a fourth preferred embodiment of the present invention preferably includes the steps of providing a laminated substrate body by stacking a plurality of ceramic layers and inner conductor layers, forming lands on the surface of the laminated substrate body to be electrically connected to the external electrodes of a mounting component, and forming a siloxane film with a thickness lower than about 100 nm so as to cover the laminated substrate body and the lands via a PVD process.

As for the manufacturing method of a ceramic multilayer substrate according to the fourth preferred embodiment of the present invention, further the method may include the steps of mounting a mounting component on the lands on which the siloxane film is formed, via solder, and forming a siloxane film with a thickness lower than about 100 nm so as to cover the mounting component and at least a portion of the solder via a PVD process.

A manufacturing method of a ceramic multilayer substrate according to a fifth preferred embodiment of the present invention preferably includes the steps of providing a laminated substrate body by stacking a plurality of ceramic layers and inner conductor layers, forming lands to be electrically connected to the external electrodes of a mounting component on the surface of the laminated substrate body, mounting the mounting component on the lands via solder, and forming a siloxane film with a thickness lower than about 100 nm so as to cover the mounting component and at least a portion of the solder via a PVD process.

As for the manufacturing methods of a ceramic multilayer substrate according to the fourth and fifth preferred embodiments of the present invention, the methods may include a step of sealing the mounting component with a resin sealing material subsequent to the step of forming the siloxane film so as to cover the mounting component via the PVD process. Further the methods may include a step of forming a siloxane film with a thickness lower than about 100 nm so as to cover the resin sealing material via the PVD process.

A manufacturing method of a ceramic multilayer substrate according to a sixth preferred embodiment of the present invention preferably includes the steps of providing a laminated substrate body by stacking a plurality of ceramic layers and inner conductor layers, forming lands to be electrically connected to the external electrodes of a mounting component on the surface of the laminated substrate body, mounting the mounting component, on the lands via solder, sealing the mounting component with a resin sealing material, and forming a siloxane film with a thickness lower than about 100 nm so as to cover the laminated substrate body and the resin sealing material via a PVD process.

A manufacturing method of a ceramic multilayer substrate according to a seventh preferred embodiment of the present invention preferably includes the steps of providing a laminated substrate body by stacking a plurality of ceramic layers and inner conductor layers, forming lands to be electrically connected to the external electrodes of a mounting component, on the surface of the laminated substrate body, forming solder balls on the lands, forming a siloxane film with a thickness below about 100 nm so as to cover the lands and the solder balls via a PVD process, forming a siloxane film with a thickness lower than about 100 nm so as to cover the mounting component via a PVD process, and mounting the mounting component on the lands via solder balls.

A manufacturing method of a ceramic multilayer substrate according to an eighth preferred embodiments of the present invention preferably includes the steps of providing a laminated substrate body by superposing a plurality of ceramic layers and inner conductor layers, forming lands to be electrically connected to the external electrodes of a mounting component, on the surface of the laminated substrate body, forming solder balls on the lands, forming a siloxane film with a thickness lower than about 100 nm so as to cover the laminated substrate body and the lands via a PVD process, forming solder balls on the mounting component, forming a siloxane film with a thickness lower than about 100 nm so as to cover the mounting component and the solder balls via a PVD process, and mounting the mounting component on the lands via solder balls.

As for the manufacturing methods of a ceramic multilayer substrate according to the seventh and eighth preferred embodiments of the present invention, the methods may include a step of sealing the mounting component with a resin sealing material subsequent to the step of mounting the mounting component. Further the methods may include a step of forming a siloxane film with a thickness lower than about 100 nm so as to cover the laminated substrate body and the resin sealing material via the PVD process.

As for the manufacturing methods of a ceramic multilayer substrate according to the fourth to eighth preferred embodiments of the present invention, the methods preferably include a step of activating the surface of the siloxane film. The step of activating the siloxane film is preferably performed by subjecting the surface of the siloxane film to cleaning using oxygen plasma.

According to various preferred embodiments of the present invention, since a siloxane film with a thickness lower than about 100 nm is arranged so as to cover a laminated substrate body and lands, by a water repellent effect, the migration resistance can be improved, and chemical environmental characteristics such as sulfuration and oxidation, are also improved. Further, since the thickness of the siloxane film is lower than approximately 100 nm, soldering and wire bonding can be performed without problems.

If both of the laminated substrate body and the mounting component mounted via solder are covered with a siloxane film, the siloxane film covers the exposed portion of the solder, thereby, thus preventing flushing out of the solder.

Moreover, when a resin sealing material for sealing the mounting component is included, the wettability between the resin sealing material and the siloxane film is good, and the bonding strength between the siloxane film and the laminated substrate body is also high, thereby enhancing the bonding strength between the resin sealing material and the laminated substrate body.

If the resin sealing material is arranged so as to cover the siloxane film, the moisture absorption of the resin sealing material is suppressed, thereby, enabling prevention of a change of the characteristics of the mounting component due to the moisture absorbed by the resin sealing material, or impurities occurred by hydrolysis of the resin sealing material.

Moreover, if the laminated substrate body and the resin sealing material are simultaneously covered with a siloxane film, the sides of the interface between the laminated substrate body and the resin sealing material are covered with the siloxane film, thereby, preventing peeling of the interface between the laminated substrate body and the resin sealing material.

If a mounting component is mounted on the substrate body via solder balls covered with the siloxane film, the flushing out of the solder can be even more reliably prevented.

Other features, elements, steps, characteristics and advantages of the present invention will be described below with reference to preferred embodiments thereof and the attached drawings.

### BRIEF DESCRIPTION OF THE DRAWINGS

FIG. 1 is a sectional view showing a first preferred embodiment of a ceramic multilayer substrate according to the present invention.

FIG. 2 is an illustrative view showing the step of forming a siloxane film.

FIG. 3 is a graph showing the relationship between the quantity of silicone based resin and the thickness of the siloxane film.

FIG. 4 is a graph showing the relationship between the quantity of silicone based resin and the area of wetting.

FIG. 5 is a sectional view showing a modified embodiment of a first preferred embodiment of a ceramic multilayer substrate according to the present invention.

FIG. 6 is a sectional view showing a second preferred embodiment of a ceramic multilayer substrate according to the present invention.

FIG. 7 is a sectional view showing a third preferred embodiment of a ceramic multilayer substrate according to the present invention.

FIG. 8 is a sectional view showing a fourth preferred embodiment of a ceramic multilayer substrate according to the present invention.

FIG. 9 is a sectional view showing a fifth preferred embodiment of a ceramic multilayer substrate according to the present invention.

FIG. 10 is a sectional view showing a modified embodiment of a fifth preferred embodiment of a ceramic multilayer substrate according to the present invention.

FIG. 11 is a sectional view showing another modified embodiment of the fifth preferred embodiment of a ceramic multilayer substrate according to the present invention.

FIG. 12 is a sectional view showing a sixth preferred embodiment of a ceramic multilayer substrate according to the present invention.

FIGS. 13A and 13B are sectional views showing a seventh preferred embodiment of a ceramic multilayer substrate according to the present invention.

FIGS. 14A and 14B are sectional views showing an eighth preferred embodiment of a ceramic multilayer substrate according to the present invention.

FIG. 15 is a sectional view showing a ninth preferred embodiment of a ceramic multilayer substrate according to the present invention.

### DETAILED DESCRIPTION OF PREFERRED EMBODIMENTS

Hereinafter, referring to the appended drawings, preferred embodiments of a ceramic multilayer substrate and manufacturing methods therefor according to the present invention will be described.

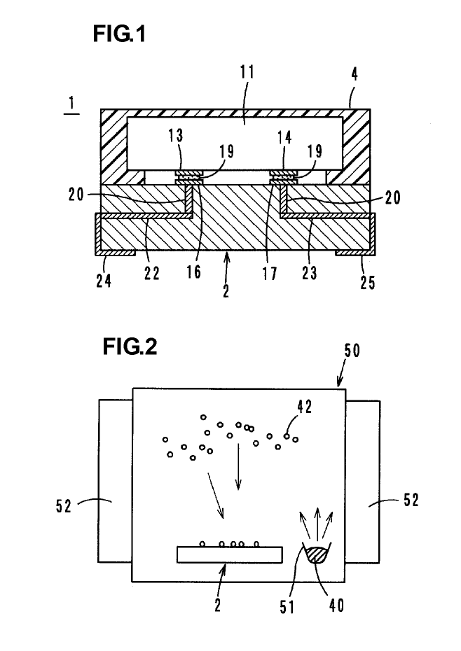

### First Preferred Embodiment (FIGS. 1 to 4)

The ceramic multilayer substrate 1 shown in FIG. 1, is substantially constituted by a laminated substrate body 2, a mounting component (IC component) 11 mounted on the laminated substrate body 2, and a resin sealing material 4 arranged to seal the mounting component 11.

Lands 16 and 17 are formed on the upper surface of the laminated substrate body 2. The mounting component 11, whose external electrodes 13 and 14 provided on its bottom surface are connected to the lands 16 and 17 via solder 19, is mounted on the laminated substrate body 2.

In the inside of the laminated substrate body 2, inner conductor patterns 22 and 23 are formed. One end of the inner conductor pattern 22 and one end of the inner conductor pattern 23 are electrically connected to lands 16 and 17, respectively, via via-hole conductors 20 formed in the laminated substrate body 2. The other ends of the inner conductor patterns 22 and 23 are electrically connected to external electrodes 24 and 25, respectively, extending from the sides to the bottom surface of the laminated substrate body 2.

The laminated substrate body 2 is preferably manufactured by the following manufacturing procedures. First, crystallized glass powder made of SiO₂, Al₂O₃, B₂O₃, and CaO, and alumina powder are blended at an equal weight ratio. By adding polyvinyl-butyral of about 15 parts by weight, isopropyl-alcohol of about 40 parts by weight, and trole of about 20 parts by weight to the blended powder of about 100 parts by weight, and blending them in a ball mill for approximately 24 hours, a slurry is made. By shaping the slurry to a sheet with a thickness of about 120 μm via a doctor blade process, a ceramic green sheet is obtained.

Next, holes for via-holes are formed in predetermined ceramic green sheets. Subsequently, conductive paste is filled in the holes for via-holes to form via-hole conductors 20, and inner conductor patterns 22 and 23 are formed on each ceramic green sheet via a screen printing process. Additionally, the via-hole conductors 20 may be formed by filling a conductive paste in holes for via-holes at the same time when the inner conductor patterns 22 and 23 are formed on each ceramic green sheet via the screen printing process.

After being stacked, the ceramic green sheets are contact bonded at a pressure of about 50 MPa, and at a temperature of about 60° C. to form a laminated block. After the laminated block is cut into pieces having a predetermined size, the pieces are sintered in a lump. In this manner, they are made as low-temperature sintered ceramic laminated substrate bodies 2.

Next, by coating conductive paste on the surface of the laminated substrate body 2, and subsequent baking thereof, lands 16 and 17, and external electrodes 24 and 25 are formed. Further, by subjecting the lands 16 and 17, and the external electrodes 24 and 25 to Ni—Au plating, a plating film is formed.

Next, as shown in FIG. 2, silicone based resin 40 contained in a crucible 51 and the laminated substrate body 2 are placed together in an oven 50 to be sealed, and heated by a heater 52. At this time, siloxane 42 that is a constituent of the silicone based resin 40 is vaporized to be deposited on the surface of the laminated substrate body 2. In this manner, the entire laminated substrate body 2 including the lands 16 and 17, and the external electrodes 24 and 25, is covered with a siloxane PVD (Physical Vapor Deposition) protective film. The thickness of the siloxane PVD protective film (hereinafter referred to as siloxane film) is preferably set lower than about 100 nm. In FIG. 1, the siloxane film is not shown.

As the siloxane film is preferably formed by means of a PVD process, rather than a CVD (Chemical Vapor Deposition) process or a plasma process, since only heating the siloxane film together with the silicone-based resin 40 is required, the siloxane film can be formed easily and at a low price.

The curing conditions for the silicone based resin 40 are, for example, about 150° C. for approximately 2 hours. When the silicone-based resin 40 is cured, its constituent siloxane 42 is vaporized, the concentration of the siloxane in the oven 50 becomes highest at about 150° C., and together with the vaporization, deposition on the surface of the laminated substrate body 2 also occurs. After the silicone-based resin 40 is cured, when the temperature within the oven 50 is lowered, the siloxane 42 is further deposited on the surface of the laminated substrate body 2, as its saturated vaporization pressure becomes smaller.

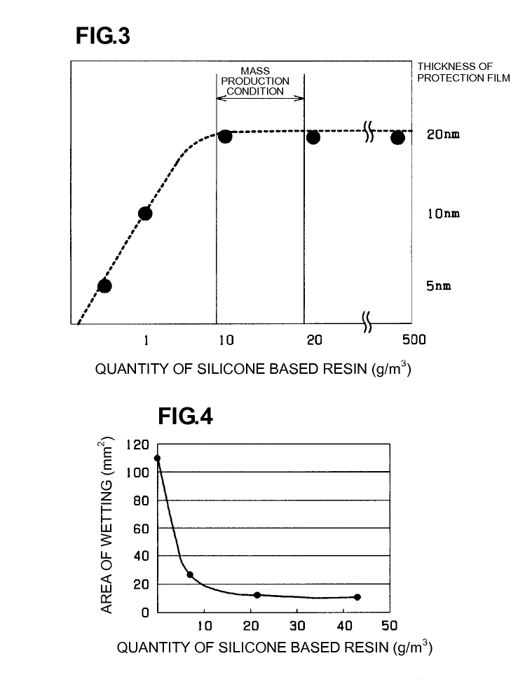

FIG. 3 is a graph showing the relationship between the quantity of the silicone-based resin 40 placed in the oven 50 and the thickness of the siloxane film formed on the laminated substrate body 2. If the silicone-based resin 40 in the oven 50 is lower than about 10 g/m³, by changing the quantity of the silicone-based resin 40, the film thickness of the siloxane film can be adjusted. If the silicone-based resin 40 in the oven 50 is about 10 g/m³ or more, the film thickness becomes a constant value of about 20 nm. This is because the concentration of the siloxane in the oven 50 is saturated.

Items as shown in Table 1 were evaluated with respect to a laminated substrate body 2 thus produced. For comparison, a laminated substrate body on which a siloxane film was not formed, was also evaluated. The occurrence of migration was evaluated under testing conditions of approximately 85° C., 85% RH, and 50 VDC. Sulfuration was evaluated by standing the substrate bodies 2 in an atmosphere of hydrogen sulfide for one minute. Solder wettability was determined as acceptable when about 95% or more of a square land of 2 mm×2 mm dipped with Sn—Pb solder was wet with solder. Wire bondability was determined as acceptable when a square land of 2 mm×2 mm bonded to a wire and had a bonding strength of 2 gf or more.

TABLE 1

| | | |
|---|---|---|
| Siloxane PVD protective film | present | not present |
| Occurrence of migration | none | occurred |
| Evaluation of sulfuration | acceptable | silver sulfide precipitated |
| | | on the edge part |
| Solder wettability | acceptable | acceptable |
| Wire bondability | min: 3.9 gf | min: 4.0 gf |

As is clear from Table 1, since the siloxane film covers the entire laminated substrate body 2 including lands 16 and 17, and external electrodes 24 and 25, the migration resistance is improved markedly. This is due to the water repellent effect of the siloxane film. FIG. 4 is a graph showing the relationship between the quantity of the silicone based resin 40 placed in the oven 50 and the wetted area of the laminated substrate body 2.

Further, environmental characteristics such as sulfuration and oxidization are also improved. Since the siloxane film is formed via a PVD process, the siloxane film is formed inside micro-level defects, thus, even migration or sulfuration originating from micro defects can also be suppressed.

Meanwhile, since the thickness of the siloxane film is as thin as lower than about 100 nm, the levels of mountability of solder wettability and wire bondability of the lands 16 and 17 and the external electrodes 24 and 25, are accceptable.

Next, the surface of the siloxane film covering the laminated substrate body 2 is activated by cleaning via a process such as plasma (preferably oxygen plasma) irradiation or ultra-violet irradiation. This enables further improvement in the wettability with respect to the resin sealing material 4. After that, the external electrodes 13 and 14 of the mounting component 11 are electrically connected and firmly fixed to the lands 16 and 17 of the laminated substrate body 2 via solder 19.

Next, the resin sealing material 4 for sealing the mounting component 11 is formed on the laminated substrate body 2. As for the material of the resin sealing material 4, a thermosetting resin such as an epoxy-based resin, or a photosensitive resin is desirable. Since the resin sealing material 4 has a good wettability with respect to the siloxane film, and the bonding strength between the silicone thin film and the laminated substrate body 2 is also high, the bonding strength between the resin sealing material 4 and the laminated substrate body 2 can be enhanced.

In addition, soldering of the mounting component 11 may be performed either before or after the formation of the siloxane film. Table 2 is a table showing evaluated results of the ceramic multilayer substrate when soldering of the mounting component 11 is performed before and after the formation of the siloxane film.

In other words, sample 1 is a ceramic multilayer substrate where, after the mounting component 11 is soldered to the laminated substrate body 2, the siloxane film is formed on the laminated substrate body 2, which is sealed with the resin sealing material 4. Sample 2 a ceramic multilayer substrate where, after the siloxane film is covered the laminated substrate body 2, the mounting component 11 is soldered to the laminated substrate body 2, which is sealed with the resin sealing material 4. For comparison, sample 3 is a ceramic multilayer substrate where, without forming the siloxane film on the laminated substrate body 2, the mounting component 11 is soldered to the laminated substrate body 2, which is sealed with the resin sealing material 4.

TABLE 2

| | Thermocycle Test | Reflow Test | |
|---|---|---|---|
| | presence or | presence or | presence or |
| | non-presence | non-presence | non-presence |
| | of peeling | of peeling | of solder shortage |
| Sample 1 | 0/10 | 0/10 | 0/10 |
| Sample 2 | 0/10 | 0/10 | 0/10 |
| Sample 3 | 1/10 | 2/10 | 1/10 |

The thermo cycle test was performed for 400 cycles at about −55° C./+125° C., and the state of peeling between the resin sealing material 4 and the laminated substrate body 2 was confirmed at the sides and at the cross section. The solder reflow test after moisture absorption was performed by standing samples for 40 hours under the conditions of approximately 60° C. and 60% RH, and subsequently, reflowing the samples at about 260° C. five times, and the state of peeling between the resin sealing material 4 and the laminated substrate body 2 was confirmed at the sides and at the cross section, and solder shortage was confirmed.

### Modification of First Prefered Embodiment (FIG. 5)

Moreover, the ceramic multilayer substrate 1A shown in FIG. 5, is substantially constituted by a laminated substrate body 2A, a mounting component 11 contained in a cavity 65 provided on the laminated substrate body 2A, and a resin sealing material 4A for sealing the mounting component 11.

On the upper side of steps in the cavity 65 of the laminated substrate body 2A, lands 16 and 17 are formed. The mounting component 11 is disposed in the cavity 65, and its external electrodes 13 and 14 are electrically connected to the lands 16 and 17 by wire bonding 61.

In the inside of the laminated substrate body 2A, internal electrode patterns 22 and 23 are formed. One end of the internal electrode pattern 22 and one end of the internal electrode pattern 23 are electrically connected to the lands 16 and 17, respectively, via via-hole conductors 20 formed in the laminated substrate body 2A. The other ends of the internal electrode patterns 22 and 23 are electrically connected to external electrodes 24 and 24, respectively.

On the lands 16 and 17 and on the external electrodes 24 and 25, a Ni—Au plating film is formed. Further, the entire laminated substrate body 2A including the lands 16 and 17 and the external electrodes 24 and 25 is covered with a siloxane film. The thickness of the siloxane film is set lower than about 100 nm. In FIG. 5, the siloxane film is not shown.

Further, a resin sealing material 4A for sealing the mounting component 11 is filled in the cavity 65 of the laminated substrate body 2A. As for the material of the resin sealing material 4A, a thermosetting resin such as an epoxy-based resin, or a photosensitive resin is desirable.

In the ceramic multilayer substrate 1A having the above-mentioned configuration, since the siloxane film covers the entire laminated substrate body 2A including the lands 16 and 17 and the external electrodes 24 and 25, the migration property is improved markedly. Meanwhile, since the thickness of the siloxane film is as thin as lower than about 100 nm, the levels of mountability of solder wettability and wire bondability of the lands 16 and 17 and the external electrodes 24 and 25 of the lands 16 and 17 and the external electrodes 24 and 25, are accceptable. The wire bonding may be performed either before or after the formation of the siloxane film. Moreover, since the resin sealing material 4A has a good wettability with respect to the siloxane film, and the bonding strength between the siloxane film and the laminated substrate body 2A is also high, the bonding strength between the resin sealing material 4 and the laminated substrate body 2A can be enhanced.

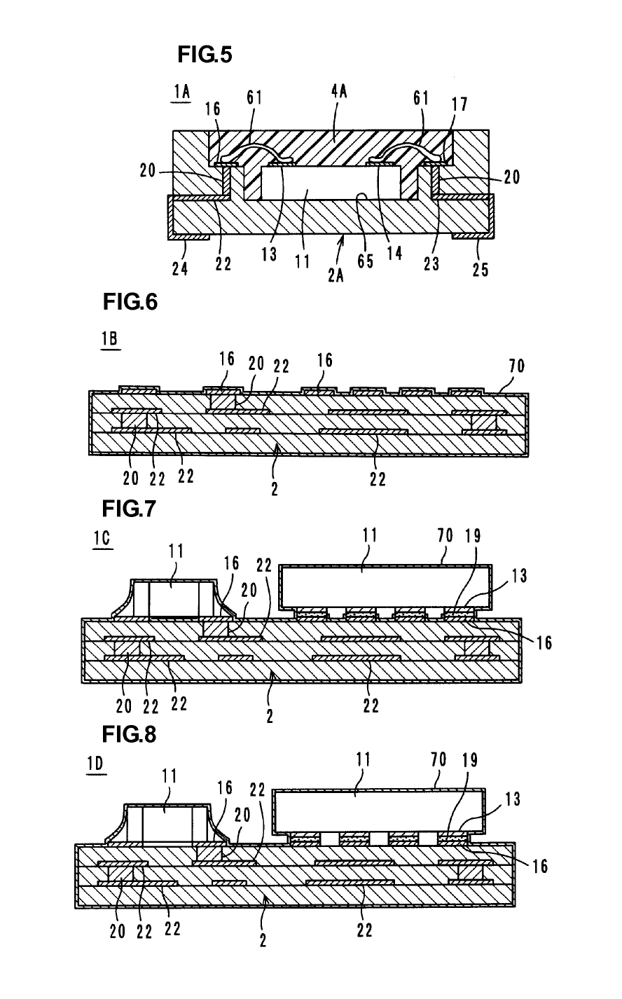

### Second Preferred Embodiment (FIG. 6)

Next, a second preferred embodiment of a ceramic multilayer substrate according to the present invention and its manufacturing method will be described. The ceramic multilayer substrate 1B shown in FIG. 6, is constituted by a laminated substrate body 2, lands 16 formed on the upper surface of the laminated substrate body 2, and a siloxane film 70 arranged so as to cover the laminated substrate body 2 and the lands 16. In the inside of the laminated substrate body 2, via-holes 20 for connecting between a conductive pattern 22 formed at an interface between layers and another conductive pattern 22 formed at another interface between layers, or the land 16, are formed.

The laminated substrate body 2 is manufactured by the following manufacturing procedures. First, crystallized glass powder made of SiO₂, Al₂O₃, B₂O₃, and CaO, and alumina powder are blended at an equal weight ratio. By adding polyvinyl-butyral of about 15 parts by weight, isopropyl-alcohol of about 40 parts by weight, and trole of 20 parts by weight to the blended powder of about 100 parts by weight, and blending them in a ball mill for approximately 24 hours, a slurry is made. By shaping the slurry to a sheet with a thickness of about 120 μm via a doctor blade process, a ceramic green sheet is obtained.

Next, holes for via-holes are formed in predetermined ceramic green sheets. Subsequently, conductive paste is filled in the holes for via-holes to form via-hole conductors 20, and inner conductor patterns 22 are formed on each ceramic green sheet by means of a screen printing process. Additionally, the via-hole conductors 20 may be formed by filling a conductive paste in holes for via-holes at the same time when the inner conductor patterns 22 are formed on each ceramic green sheet via the screen printing process.

After being stacked, the ceramic green sheets are contact bonded at a pressure of about 50 MPa, and at a temperature of about 60° C. to form a laminated block. After the laminated block is cut into pieces having a predetermined size, the pieces are sintered in a lump. In this manner, they are made as low-temperature sintered ceramic laminated substrate bodies 2.

Next, by coating conductive paste on the surface of the laminated substrate body 2, and subsequent baking thereof, lands 16 are formed. In addition, the lands 16 may be formed by forming a land pattern on a ceramic green sheet, and by sintering the land pattern and the ceramic green sheet, simultaneously. Further, a plating film may be formed by subjecting the lands 16 to Ni—Au plating. In addition, the plating film may not be formed.

Next, using a method similar to that of the above-mentioned first preferred embodiment, a ceramic multilayer substrate 1B is produced by forming a siloxane film 70 with a thickness lower than about 100 nm on the laminated substrate body 2 so as to cover the laminated substrate body 2 and the lands 16. In addition, in FIG. 6, although the whole surface of the laminated substrate body 2 is covered with the siloxane film, at least the principal surface on which the lands 16 are formed, should be covered, for example, the bottom surface may not be covered.

In the ceramic multilayer substrate 1B having the above-mentioned configuration, since the siloxane film 70 covers the entire laminated substrate body 2 including the lands 16, the migration resistance can be improved markedly, and environmental characteristics such as sulfuration and oxidization are also improved. Meanwhile, since the thickness of the siloxane film 70 is as thin as lower than about 100 nm, the levels of mountability of solder wettability and wire bondability of the lands 16, are acceptable.

### Third Preferred Embodiment (FIG. 7)

Next, a third preferred embodiment of a ceramic multilayer substrate according to the present invention and its manufacturing method will be described. The ceramic multilayer substrate 1C shown in FIG. 7, is substantially constituted by a laminated substrate body 2, mounting components 11 mounted on the laminated substrate body 2, and a siloxane film 70 arranged so as to cover the laminated substrate body 2 and the mounting components 11.

On the upper surface of the laminated substrate body 2, lands 16 are formed. The mounting component 11, whose external electrodes provided on its bottom surface are bonded to the lands 16 via solder 19, is mounted on the laminated substrate body 2. At least a portion of such a portion of the lands 16 that is not contacted to the solder 19 and exposed, is covered with the siloxane film 70. At least a portion of the portion of the solder 19 which is exposed and not contacted to the lands 16 and the external electrodes 13, is covered with the siloxane film 70. In the inside of the laminated substrate body 2, via-holes 20 for connecting between a conductive pattern 22 formed at an interface between layers and another conductive pattern 22 formed at another interface between layers, or the land 16, are formed. In addition, in FIG. 7, as for the mounting component 11, whose external electrodes 13 are formed on its bottom surface, of the mounting components 11, on the sides of the external electrodes 13 formed on the center of the mounting component 11 and on the sides of the solder 19 connected to the external electrodes 13, the siloxane film 70 is not formed, however, the siloxane film 70 may be formed on these portions.

The ceramic multilayer substrate 1C is preferably manufactured by the following procedures. The laminated substrate body 2 is preferably formed by a method similar to that of the above-mentioned second preferred embodiment. Next, by a method similar to that of the above-mentioned first preferred embodiment, a siloxane film 70 with a thickness lower than about 100 nm is formed. Next, the mounting components 11 are mounted on the lands 16 on which the siloxane film 70 is formed, via the solder 19. After that, by the method similar to that of the above-mentioned first preferred embodiment, the siloxane film 70 is formed again so as to cover the mounting components 11 and at a least portion of such a portion of the solder 19 that is not contacted to the lands 16 and the external electrodes 13, and exposed. In addition, at that time, the siloxane film 70 may be formed further on the laminated substrate body 2.

In the ceramic multilayer substrate 1C having the above-mentioned configuration, since the siloxane film 70 covers the entire laminated substrate body 2 including the lands 16, the migration resistance can be improved markedly, and environmental characteristics such as sulfuration and oxidization are also improved. Moreover, since the mounting components 11 are also covered with the siloxane film 70, chemical envioronmental characteristics such as sulfuration or oxidation of the mounting components 11 is also improved. Meanwhile, since the thickness of the siloxane film 70 is as thin as lower than about 100 nm, the levels of mountability of solder wettability and wire bondability of the lands 16, are acceptable. Further, since the siloxane film 70 covers at least a portion of the solder 19, in a reflow step when the ceramic multilayer substrate 1C is mounted on the other substrate, flushing out of the solder 19 is prevented.

### Fourth Preferred Embodiment (FIG. 8)

Next, a fourth preferred embodiment of a ceramic multilayer substrate according to the present invention and its manufacturing method will be described. The ceramic multilayer substrate 1D shown in FIG. 8, is substantially constituted by a laminated substrate body 2, mounting components 11 mounted on the laminated substrate body 2, and a siloxane film 70 arranged so as to cover the laminated substrate body 2 and the mounting components 11.

On the upper surface of the laminated substrate body 2, lands 16 are formed. The mounting component 11, whose external electrodes 13 provided on its bottom surface are connected to the lands 16 via solder 19, is mounted on the laminated substrate body 2. At least a portion of the lands 16 which is exposed and not contacted to the solder 19, is covered with the siloxane film 70. Moreover, at least a portion of such a portion of the solder 19 that is not contacted to the lands 16 and the external electrodes 13, and exposed, is covered with the siloxane film 70.

In the inside of the laminated substrate body 2, via-holes 20 for connecting between a conductive pattern 22 formed at an interface between layers and another conductive pattern 22 formed at another interface between layers, or the land 16, are formed. In addition, in FIG. 8, as for the mounting component 11, whose external electrodes 13 are formed on its bottom surface, of the mounting components 11, on the sides of the external electrodes 13 formed on the center of the mounting component 11 and on the sides of the solder 19 and lands 16 connected to the external electrodes 13, the siloxane film 70 is not formed, however, the siloxane film 70 may be formed on these portions.

The ceramic multilayer substrate 1D is preferably manufactured by the following procedures. The laminated substrate body 2 is formed by a method similar to that of the above-mentioned second preferred embodiment. Next, the mounting components 11 are mounted on the lands 16 via the solder 19. After that, using the method similar to that of the above-mentioned first preferred embodiment, the siloxane film 70 is formed again so as to cover the mounting components 11 and at a least portion of such a portion of the solder 19 that is not contacted to the lands 16 and the external electrodes 13, and exposed.

In the ceramic multilayer substrate 1D having the above-mentioned configuration, since the siloxane film 70 covers the laminated substrate body 2 mounting components 11, and at least a portion of the lands 16, the migration resistance can be improved markedly, and environmental characteristics such as sulfuration and oxidization are also improved. Moreover, since the mounting components 11 are also covered with the siloxane film 70, chemical envioronmental characteristics such as sulfuration or oxidation of the mounting components 11 are also improved. Moreover, since the siloxane film 70 covers at least a portion of the solder 19, in a reflow step when the ceramic multilayer substrate 1D is mounted on the other substrate, flushing out of the solder 19 is suppressed.

### Fifth Preferred Embodiment (FIG. 9)

Next, a fifth preferred embodiment of a ceramic multilayer substrate according to the present invention and its manufacturing method will be described. The ceramic multilayer substrate 1E shown in FIG. 9, is constituted by a laminated substrate body 1B (see the second preferred embodiment and FIG. 6), mounting components 11 mounted on the laminated substrate body 1B, a resin sealing material 4 arranged to seal the mounting components, and a siloxane film 70 arranged so as to cover the resin sealing material 4.

On the upper surface of the ceramic multilayer substrate 1B, lands 16 covered with the siloxane film 70 are formed. The mounting component 11, whose external electrodes 13 provided on its bottom surface is bonded to the lands 16 via solder 19, is mounted on a laminated substrate body 2.

The ceramic multilayer substrate 1E is preferably manufactured by the following procedures. The surface of the siloxane film 70 covering the ceramic multilayer substrate 1B produced by a method similar to that of the above-mentioned second preferred embodiment is activated by cleaning via a process such as plasma (preferably, oxygen plasma) irradiation or ultraviolet irradiation. Next, on the lands 16 of the ceramic multilayer substrate 1B, the mounting components 11 are mounted via the solder 19. Next a resin sealing material 4 for sealing the mounting components 11 is formed. As for the material of the resin sealing material 4, a material similar to that described in the first preferred embodiment may preferably be used. After that, using a method similar to that of the above-mentioned first preferred embodiment, the siloxane film 70 is formed so as to cover the resin sealing material 4. In addition, at this time, the siloxane film 70 may be formed further on the laminated substrate body 2. In FIG. 9, although the siloxane film 70 is formed on the resin sealing material 4, rather, the siloxane film 70 may not be formed so as to cover the resin sealing material 4.

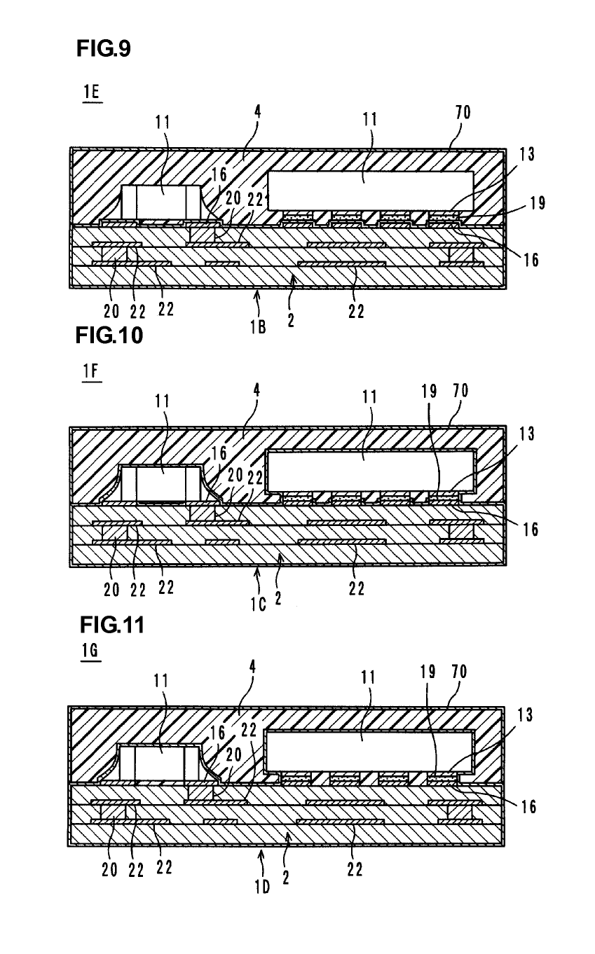

### Modification of Fifth Preferred Embodiment (FIGS. 10 and 11)

Similarly, as for ceramic multilayer substrates 1F and 1G, shown in FIGS. 10 and 11, they respectively include the ceramic multilayer substrate 1C (see the third preferred embodiment and FIG. 7) and the resin sealing material 4 on which a siloxane film 70 is formed, and the ceramic multilayer substrate 1D (see the fourth preferred embodiment and FIG. 8) and the resin sealing material 4 on which a siloxane film 70 is formed. The methods for forming the resin sealing material 4 and the siloxane film 70 are similar to those of in the first preferred embodiment. Although, in FIGS. 10 and 11, the siloxane film 70 is formed on the resin sealing material 4, rather, the siloxane film 70 may not be formed so as to cover the resin sealing material 4.

In the ceramic multilayer substrates 1E, 1F, and 1G having the above-mentioned configurations, in addition to the effects of the ceramic multilayer substrates 1B, 1C, and 1D, the following effects can be obtained. Since the siloxane film 70 is formed on the interface between the resin sealing material 4 and the laminated substrate body 2, the bonding strength between the resin sealing material 4 and the laminated substrate body 2 can be enhanced. When the resin sealing material 4 is covered with the siloxane film 70, the moisture absorption of the resin sealing material 4 can be prevented, thereby, preventing changes in the characteristics of the mounting components 11 due to the moisture absorbed by the resin sealing material 4, or impurities occurred by hydrolytic cleavage of the resin sealing material 4. Further, when the siloxane film 70 covers the sides of the interface between the resin sealing material 4 and the laminated substrate body 2, peeling of the interface between the laminated substrate body 2 and the resin sealing material 4 can be more reliably prevented.

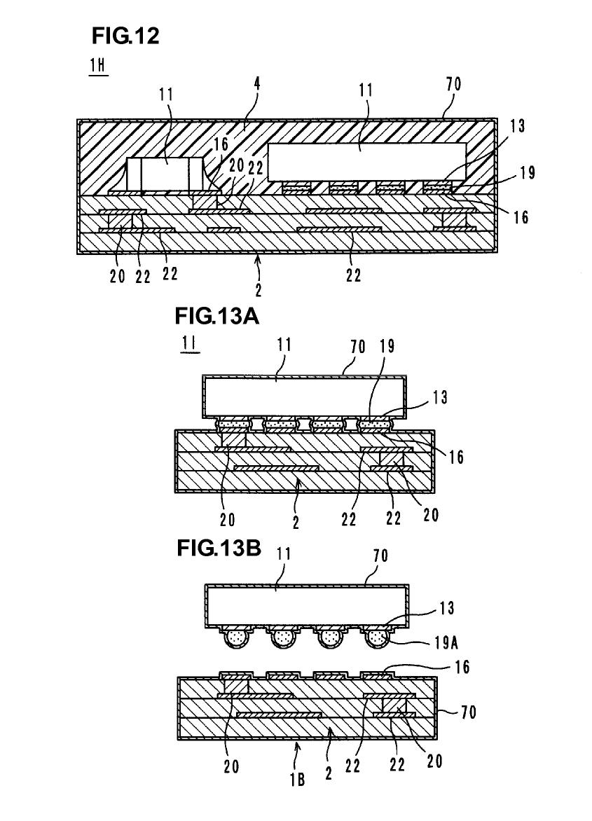

### Sixth Preferred Embodiment (FIG. 12)

Next, a sixth preferred embodiment of a ceramic multilayer substrate according to the present invention and its manufacturing method will be described. The ceramic multilayer substrate 1H shown in FIG. 12, is constituted by a laminated substrate body 2, mounting components 11 mounted on the laminated substrate body 2, a resin sealing material 4 arranged to seal the mounting components 11, and a siloxane film 70 arranged so as to cover the laminated substrate body 2 and the resin sealing material 4.

On the upper surface of the laminated substrate body 2, lands 16 are formed. The mounting component 11, whose external electrodes 13 provided on its bottom surface is bonded to the lands 16 via solder 19, is mounted on the laminated substrate body 2.

The ceramic multilayer substrate 1H is manufactured by the following procedures. On the lands 16 of the ceramic multilayer substrate 2 produced by a method similar to that of the second preferred embodiment, the mounting components 11 are mounted via the solder 19. Next, the resin sealing material 4 for sealing the mounting components 11 is formed. As for the material of the resin sealing material 4, a material similar to that described in the first preferred embodiment can be used. After that, using a method similar to that of the first preferred embodiment, the siloxane film is formed so as to cover the laminated substrate body 2 and the resin sealing material 4.

In the ceramic multilayer substrate 1H having the above-mentioned configuration, since the siloxane film 70 is covered with the siloxane film 70, the moisture absorption of the resin sealing material 4 can be prevented, thereby, preventing changes in the characteristics of the mounting components 11 due to the moisture absorbed by the resin sealing material 4, or impurities occurred by hydrolytic cleavage of the resin sealing material 4. Further, since the siloxane film 70 covers the sides of the interface between the resin sealing material 4 and the laminated substrate body 2, peeling of the interface between the laminated substrate body 2 and the resin sealing material 4 can be more reliably prevented.

### Seventh Preferred Embodiment (FIGS. 13A and 13B)

Next, a seventh preferred embodiment of a ceramic multilayer substrate according to the present invention and its manufacturing method will be described. The ceramic multilayer substrate 1I shown in FIG. 13A, is constituted by a laminated substrate body 2, lands 16 formed on the upper side of the laminated substrate body 2, a mounting component 11 mounted on the lands 16 via solder 19, and a siloxane film 70 arranged so as to cover the laminated substrate body 2 the mounting component 11 and at least a portion of the solder 19. In the inside of the laminated substrate body 2, via-holes 20 for connecting between a conductive pattern 22 formed at an interface between layers and another conductive pattern 22 formed at another interface between layers, or the land 16, are formed.

The ceramic multilayer substrate 1I is manufactured by the following procedures. As shown in FIG. 13B, first, by means of a method similar to that of the above-mentioned second preferred embodiment, a ceramic multilayer substrate 1B, in which the laminated substrate body 2 and lands 16 formed on the upper surface of the laminated substrate body 2 are covered with the siloxane film 70, is produced. Meanwhile, solder balls 19A are formed on the external electrodes 13 of the mounting component 11, after that, the siloxane film 70 is formed so as to cover the mounting component 11 and the solder balls 19A. The siloxane film 70 is preferably formed by a method similar to that of the above-mentioned first preferred embodiment. Next, by arranging the mounting component 11 covered with the siloxane film 70 on the ceramic multilayer substrate 1B such that the solder balls 19A and the lands 16 correspond respectively, and subjecting the mounting component 11 to a heat treatment, the mounting component 11 is connected to the upper surface of the ceramic multilayer substrate 1B, thereby resulting in the production of the ceramic multilayer substrate 1I.

In the ceramic multilayer substrate 1I having the above-mentioned configuration, since the siloxane film 70 covers the sides of the lands 16 that are not contacted to the solder 19 and the entire laminated substrate body 2, the migration resistance can be improved markedly, thereby, chemical environmental characteristics such as sulfuration or the oxidation are also improved. Moreover, since the mounting component 11 is also covered with the siloxane film 70, chemical environmental characteristics such as sulfuration or the oxidation of the mounting component 11, are also improved. Further, since all of the sides of the solder 19 which are not contacted to the lands 16 and the external electrodes 13 of the mounting component 11, are covered with the siloxane film 70, in a reflow step when the ceramic multilayer substrate 1I is mounted on the other substrate, flushing out of the solder 19 is reliably prevented. Meanwhile, since the thickness of the siloxane film is as thin as lower than about 100 nm, the siloxane film is caused to be moved due to the heat treatment in a soldering step, thereby, connectability via solder is acceptable.

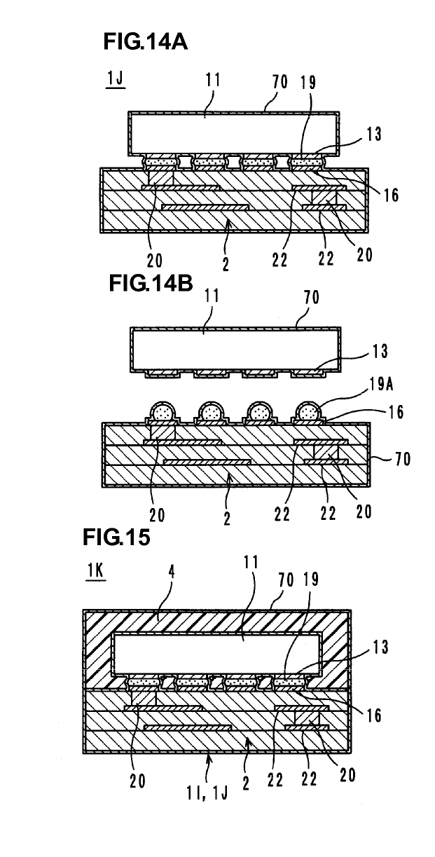

### Eigth Preferred Embodiment (FIGS. 14A and 14B)

Next, an eighth preferred embodiment of a ceramic multilayer substrate according to the present invention and its manufacturing method will be described. The ceramic multilayer substrate 1J shown in FIG. 14A, is constituted by a laminated substrate body 2, lands 16 formed on the upper side of the laminated substrate body 2, a mounting component 11 mounted on the lands 16 via solder 19, and a siloxane film 70 arranged so as to cover the laminated substrate body 2 the mounting component 11 and at least a portion of the solder 19. In the inside of the laminated substrate body 2, via-holes 20 for connecting between a conductive pattern 22 formed at an interface between layers and another conductive pattern 22 formed at another interface between layers, or the land 16, are formed.

The ceramic multilayer substrate 1J is manufactured by the following procedures. As shown in FIG. 14B, first, solder balls 19A are formed on the lands 16 formed on the upper surface of the laminated substrate body 2. Next, the siloxane film 70 is formed so as to cover the laminated substrate body 2 and the solder balls 19A. Meanwhile, the siloxane film 70 is formed so as to cover the mounting component 11 and its external electrodes 13. The siloxane film 70 is formed by a method similar to that of the first preferred embodiment. Next, by arranging the mounting component 11 covered with the siloxane film 70 on the ceramic multilayer substrate 1B such that the solder balls 19A and the lands 16 correspond respectively, and subjecting the mounting component 11 to a heat treatment, the mounting component 11 is connected to the upper surface of the laminated substrate body 2, thereby, resulting in the production of the ceramic multilayer substrate 1J.

In the ceramic multilayer substrate 1J having the above-mentioned configuration, since the siloxane film 70 covers the sides of the lands 16 that are not contacted to the solder 19 and the entire laminated substrate body 2, the migration resistance can be improved markedly, thereby, chemical environmental characteristics such as sulfuration or the oxidation are also improved. Moreover, since the mounting component 11 is also covered with the siloxane film 70, thereby, chemical environmental characteristics such as sulfuration or the oxidation of the mounting component 11 are also improved. Further, since all of the sides of the solder 19 which are not contacted to the lands 16 and the external electrodes 13 of the mounting component 11, are covered with the siloxane film 70, in a reflow step when the ceramic multilayer substrate 1J is mounted on the other substrate, flushing out of the solder 19 is reliably prevented. Meanwhile, since the thickness of the siloxane film is as thin as lower than about 100 nm, the siloxane film is caused to be moved due to the heat treatment in a soldering step, thereby, connectability via solder is acceptable.

### Ninth Preferred Embodiment (FIG. 15)

Next, a ninth preferred embodiment of a ceramic multilayer substrate according to the present invention and its manufacturing method will be described. The ceramic multilayer substrate 1K shown in FIG. 15, is constituted by a laminated substrate body 1I (see the seventh preferred embodiment and FIG. 13) or a laminated substrate body 1J (see the eighth preferred embodiment and FIG. 14), a resin sealing material 4 arranged to seal the mounting component 11 on the ceramic multilayer substrate 1I or 1J, and a siloxane film 70 arranged so as to cover the resin sealing material 4.

The ceramic multilayer substrate 1K is preferably manufactured by the following procedures. The surface of the siloxane film 70 covering the ceramic multilayer substrate 1I or 1J produced by means of a method similar to that of the above-mentioned seventh and eighth preferred embodiments, is activated by cleaning via a process such as plasma (preferably, oxygen plasma) irradiation or ultraviolet irradiation. Next, on the ceramic multilayer substrate 1I or 1J, the resin sealing material 4 for sealing the mounting component 11 is formed. As for the material of the resin sealing material 4, a material similar to that described in the first preferred embodiment can be used. After that, using a method similar to that of the above-mentioned first preferred embodiment, the siloxane film 70 is formed so as to cover the resin sealing material 4. In addition, at this time, the siloxane film 70 may be formed further on the laminated substrate body 2. In FIG. 15, although the siloxane film 70 is formed on the resin sealing material 4, rather, the siloxane film 70 may not be formed so as to cover the resin sealing material 4.

In the ceramic multilayer substrate 1K having the above-mentioned configuration, in addition to the effects of the ceramic multilayer substrates 1I and 1J, the following effects can be obtained. Since the siloxane film 70 is formed at the interface between the resin sealing material 4 and the laminated substrate body 2, the bonding strength between the resin sealing material 4 and the laminated substrate body 2 can be enhanced. When the resin sealing material 4 is covered with the siloxane film 70, the moisture absorption of the resin sealing material 4 is minimized, thereby, preventing changes of the characteristics of the mounting component 11 due to the moisture absorbed by the resin sealing material 4, or impurities occurred by hydrolytic cleavage of the resin sealing material 4. Further, when the siloxane film 70 covers the sides of the interface between the resin sealing material 4 and the laminated substrate body 2, peeling of the interface between the laminated substrate body 2 and the resin sealing material 4 can be more reliably prevented.

### Another Preferred Embodiment

In addition, the ceramic multilayer substrates according to the present invention and its manufacturing methods are not intended to be limited to the above-mentioned preferred embodiments, rather, they can be changed variously within the scope of the present invention.

For example, in the above-mentioned preferred embodiments, embodiments where the laminated substrate body is formed by stacking ceramic green sheets, were shown, however, an embodiment where the laminated substrate body is formed by a method of alternately recoating ceramic paste and conductive paste, may be possible.

As above, preferred embodiments of the present invention are useful for a ceramic multilayer substrate for mounting an electronic component such as an IC component on the surface thereof, and its manufacturing method, especially, it is excellent in that the migration resistance is good, and the bonding strength between a resin sealing material and a ceramic multilayer substrate body becomes higher.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A ceramic multilayer substrate comprising:
a laminated substrate body including a plurality of ceramic layers and inner conductor layers stacked on each other;
a land provided on a surface of the laminated substrate body and arranged to electrically connect to external electrodes of a mounting component; and
a siloxane film arranged so as to cover the laminated substrate body and the land, the siloxane film having a thickness that is less than about 100 nm.

2. The ceramic multilayer substrate according to claim 1, wherein the siloxane film is arranged so as to cover the mounting component mounted on the land via solder and at least a portion of the solder.

3. A ceramic multilayer substrate comprising:
a laminated substrate body including a plurality of ceramic layers and inner conductor layers stacked on each other;
a land provided on a surface of the laminated substrate body and arranged to electrically connect to external electrodes of a mounting component;
the mounting component mounted on the land via solder; and
a siloxane film arranged so as to cover the laminated substrate body, the mounting component, and at least a portion of the solder, and the siloxane film having a thickness that is less than about 100 nm.

4. The ceramic multilayer substrate according to claim 1, further comprising a resin sealing material arranged to seal the mounting component.

5. The ceramic multilayer substrate according to claim 4, wherein the resin sealing material is covered with the siloxane film.

6. The ceramic multilayer substrate according to claim 3, further comprising a resin sealing material arranged to seal the mounting component.

7. The ceramic multilayer substrate according to claim 6, wherein the resin sealing material is covered with the siloxane film.

8. A ceramic multilayer substrate comprising:
a laminated substrate body including a plurality of ceramic layers and inner conductor layers stacked on each other;
a land provided on a surface of the laminated substrate body and arranged to electrically connect to external electrodes of a mounting component;
the mounting component mounted on the land via solder;
a resin sealing material arranged to seal the mounting component; and
a siloxane film arranged so as to cover the laminated substrate body and the resin sealing material, and the siloxane film having a thickness that is less than about 100 nm.

9. The ceramic multilayer substrate according to claim 8, wherein the mounting component includes an IC component and is electrically connected to the lands via wire bonding.

10. The ceramic multilayer substrate according to claim 9, wherein the IC component is contained in a cavity provided on one principal surface of the laminated substrate body.

11. The ceramic multilayer substrate according to claim 1, wherein a plating film is disposed on the land.

12. A method of manufacturing a ceramic multilayer substrate, comprising the steps of:
forming a laminated substrate body by stacking a plurality of ceramic layers and inner conductor layers;
forming lands on a surface of the laminated substrate body for electrical connection to external electrodes of a mounting component; and
forming a siloxane film with a thickness lower than about 100 nm via a PVD process so as to cover the laminated substrate body and the land.

13. The method of manufacturing of a ceramic multilayer substrate according to claim 12, further comprising the steps of:
mounting the mounting component on the lands, on which the siloxane film is formed, via solder; and
forming a siloxane film with a thickness lower than about 100 nm via a PVD process so as to cover the mounting component and at least a portion of the solder.

14. A method of manufacturing of a ceramic multilayer substrate, comprising the steps of:
forming a laminated substrate body by stacking a plurality of ceramic layers and inner conductor layers;
forming lands on a surface of the laminated substrate body for electrical connection to external electrodes of a mounting component;
mounting the mounting component on the land via solder; and
forming a siloxane film with a thickness lower than about 100 nm via a PVD process so as to cover the laminated substrate body, the mounting component, and at least a portion of the solder.

15. The method of manufacturing of a ceramic multilayer substrate according to claim 14, further comprising a step of sealing the mounting component with a sealing material, subsequent to the step of forming the siloxane film with a thickness lower than about 100 nm via the PVD process so as to cover the mounting substrate.

16. The method of manufacturing of a ceramic multilayer substrate according to claim 15, further comprising a step of forming a siloxane film with a thickness lower than about 100 nm via a PVD process so as to cover the resin sealing material.

17. A method of manufacturing of a ceramic multilayer substrate, comprising the steps of:
forming a laminated substrate body by stacking a plurality of ceramic layers and inner conductor layers;
forming lands on the surface of the laminated substrate body for electrical connection to external electrodes of a mounting component;
mounting the mounting component on the land via solder;
sealing the mounting component with a sealing material; and
forming a siloxane film with a thickness lower than about 100 nm via a PVD process so as to cover the laminated substrate body and the resin sealing material.

18. A method of manufacturing of a ceramic multilayer substrate, comprising the steps of:
forming a laminated substrate body by stacking a plurality of ceramic layers and inner conductor layers;
forming lands on a surface of the laminated substrate body for electrical connection to external electrodes of a mounting component;
forming solder balls on the land;
forming a siloxane film with a thickness lower than about 100 nm via a PVD process so as to cover the laminated substrate body, the land, and the solder ball;
forming another siloxane film with a thickness lower than about 100 nm via the PVD process so as to cover the mounting substrate; and
mounting the mounting component on the land via the solder ball.

19. A method of manufacturing of a ceramic multilayer substrate, comprising the steps of:
forming a laminated substrate body by stacking a plurality of ceramic layers and inner conductor layers;
forming lands on the surface of the laminated substrate body for electrical connection to external electrodes of a mounting component;
forming a siloxane film with a thickness lower than about 100 nm via a PVD process so as to cover the laminated substrate body and the land;
forming a solder ball on the mounting component;
forming another siloxane film with a thickness lower than about 100 nm via the PVD process so as to cover the mounting component and the solder ball; and
mounting the mounting component on the land via the solder ball.

20. The method of manufacturing of a ceramic multilayer substrate according to claim 19, further comprising a step of sealing the mounting component with a resin sealing material, subsequent to the step of mounting the mounting component.

21. The method of manufacturing of a ceramic multilayer substrate according to claim 20, further comprising a step of forming a siloxane film with a thickness lower than about 100 nm via a PVD process so as to cover the laminated substrate body and the resin sealing material.

22. The method of manufacturing of a ceramic multilayer substrate according to claim 21, further comprising a step of activating a surface of the siloxane film.

23. The method of manufacturing of a ceramic multilayer substrate according to claim 22, wherein the step of activating a surface of the siloxane film is performed by subjecting the surface of the siloxane film to cleaning using oxygen plasma.
